(19) United States
(12) Patent Application Publication
(10) Pub. No.: US 2024/0421062 A1
(43) Pub. Date: Dec. 19, 2024

(54) PLUGGABLE INTERCONNECTS USING GLASS CORES OF INTEGRATED CIRCUIT PACKAGE SUBSTRATES

(71) Applicant: Intel Corporation, Santa Clara, CA (US)

(72) Inventors: Tolga Acikalin, San Jose, CA (US); Shuhei Yamada, Vancouver, WA (US); Telesphor Kamgaing, Chandler, AZ (US); Tae Young Yang, Portland, OR (US)

(21) Appl. No.: 18/334,188

(22) Filed: Jun. 13, 2023

(51) Int. Cl. H01L 23/498; H01L 21/3205; H01L 23/00; H01L 23/15; H01L 23/49; H01L 23/538; H01L 23/544; H01L 25/065

(52) U.S. Cl. CPC H01L 23/49838; H01L 21/32051; H01L 23/15; H01L 23/49; H01L 23/49833; H01L 23/5384; H01L 23/544; H01L 24/16; H01L 25/0655; H01L 2223/54426; H01L 2224/16225; H01L 2924/15174; H01L 2924/15788

(57) ABSTRACT

Wireless interconnects in integrated circuit package substrates with glass cores are disclosed. An example apparatus includes a semiconductor die and a substrate including a glass core. The apparatus also includes a pluggable interconnect including a portion of the glass core. The pluggable interconnect includes a transmission line extending along the portion of the glass core.

### FIELD OF THE DISCLOSURE

This disclosure relates generally to integrated circuit packages and, more particularly, to pluggable interconnects using glass cores of integrated circuit package substrates.

### BACKGROUND

Integrated circuit (IC) chips and/or semiconductor dies are routinely connected to larger circuit boards such as motherboards and other types of printed circuit boards (PCBs) via a package substrate. Integrated circuit (IC) chips and/or dies have exhibited reductions in size and increases in interconnect densities as technology has advanced.

### BRIEF DESCRIPTION OF THE DRAWINGS

FIG. 1 illustrates an example integrated circuit (IC) package on a printed circuit board.

FIGS. 2-5 are perspective views of different example IC packages constructed in accordance with teachings disclosed herein.

FIG. 6 is a cross-sectional view of an example package substrate with an example pluggable interconnect plugged into an example plug connector in accordance with teachings disclosed herein.

FIG. 7 shows the example package substrate of FIG. 6 with the example pluggable interconnect plugged into another example plug connector.

FIG. 8 is a cross-sectional view of another example package substrate with an example pluggable interconnect plugged into another example plug connector in accordance with teachings disclosed herein.

FIG. 9 is a cross-sectional view of another example package substrate with an example pluggable interconnect plugged into another example plug connector in accordance with teachings disclosed herein.

FIG. 10 is a cross-sectional view of another example package substrate with an example pluggable interconnect plugged into another example plug connector in accordance with teachings disclosed herein.

FIG. 11 is a flowchart representative of an example method of manufacturing any one of the example IC packages of FIG. 1-5 with any one of the example package substrates of FIGS. 6-10.

FIG. 12 is a top view of a wafer including dies that may be included in an IC package constructed in accordance with teachings disclosed herein.

FIG. 13 is a cross-sectional side view of an IC device that may be included in an IC package constructed in accordance with teachings disclosed herein.

FIG. 14 is a cross-sectional side view of an IC device assembly that may include an IC package constructed in accordance with teachings disclosed herein.

FIG. 15 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

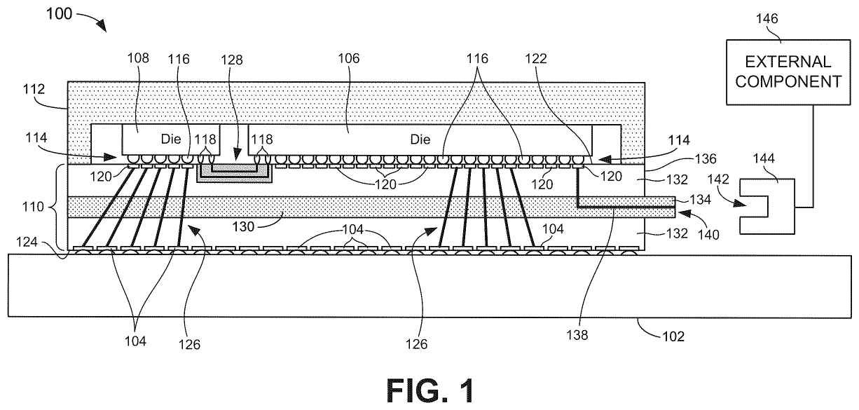

FIG. 1 illustrates an example integrated circuit (IC) package 100 constructed in accordance with teachings disclosed herein. In the illustrated example, the IC package 100 is electrically coupled to a circuit board 102 (e.g., a printed circuit board (PCB), a motherboard, etc.) via an array of contact pads or lands 104 on a mounting surface 124 (e.g., a bottom surface) of the package 100. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.). As one specific example, the IC package 100 may correspond to programmable circuitry such as a microprocessor and the dies 106, 108 correspond to separate cores of the processor.

As shown in the illustrated example, each of the dies 106, 108 is electrically and mechanically coupled to the substrate 110 via corresponding arrays of interconnects 114. In FIG. 1, the interconnects 114 are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the landing pads 104 on the bottom (external) surface 124 of the substrate 110 (e.g., a surface opposite the inner surface 122) via internal interconnects 126 within the substrate 110. As a result, there is a continuous electrical signal path between the interconnects 114 of the dies 106, 108 and the landing pads 104 mounted to the circuit board 102 that pass through the contact pads 120 and the interconnects 126 provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 128 embedded in the package substrate 110. As represented in FIG. 1, core bumps 116 are typically larger than bridge bumps 118. In some examples, the interconnect bridge 128 and the associated bridge bumps 118 are omitted.

In FIG. 1, the substrate 110 of the example IC package 100 includes a glass substrate, layer, or core 130 between two separate build-up layers or regions 132. In some examples, glass substrates (e.g., the glass core 130) include quartz, fused silica, and/or borosilicate glass. In some examples, glass substrates (e.g., the glass core 130) includes at least 20% (by weight) of each of silicon (Si) and oxygen (O). In other examples, glass substrates (e.g., the glass core 130) includes greater amounts of at least one of silicon or oxygen (e.g., at least 25 wt %, at least 30 wt %, at least 35 wt %, at least 40 wt %, etc.). In some examples, glass substrates (e.g., the glass core 130) includes at least 5% (by weight) of aluminum (Al). In accordance with the present disclosure, glass substrates (e.g., the glass core 130) include at least one glass layer and do not include epoxy and do not include glass fibers (e.g., do not include an epoxy-based prepreg layer with glass cloth). In some examples, glass substrates (e.g., the glass core 130) correspond to a single piece of glass that extends the full height/thickness of the core. In some examples, the glass core 130 has a generally rectangular shape that is substantially coextensive, in plan view, with the layers above and below the core (e.g., substantially coextensive with the build-up regions 132). However, as detailed further below, in some examples, there is at least one extension of the glass core 130 from the build-up regions 132. In some such examples, the at least one extension also extends from the generally rectangular shape of the glass core 130. Among other things, glass cores are advantageous over epoxy-based cores because glass is stiffer and, therefore, provides for greater mechanical support or strength for the package substrate. Thus, the glass core 130 is an example means for strengthening the package substrate.

The build-up regions 132 are represented in FIG. 1 as masses/blocks with the internal interconnects 126 extending in straight lines through the build-up regions 132 (and the glass core 130). However, FIG. 1 has been simplified for the sake of clarity and purposes of explanation. In practice, the interconnects are not necessarily straight. More particularly, in some examples, the build-up regions 132 are defined by alternating layers of dielectric material and layers of conductive material (e.g., a metal such as copper). The conductive (metal) layers serve as the basis for the internal interconnects 126 represented, in a simplified form, by straight lines as shown in FIG. 1. In some examples, the metal layers are patterned to define electrical routing or conductive traces that are electrically coupled between different metal layers by conductive (e.g., metal) vias extending through intervening dielectric layers. Further, the electrical routing or traces on either side of the glass core 130 may be electrically coupled by through-glass vias (TGVs) (e.g., copper plated vias) extending through the glass core 130.

As shown in the illustrated example, the glass core 130 includes and/or defines a protrusion 134 that extends or protrudes beyond an outer surface, perimeter, or lateral edge 136 of the package 100 (e.g., the outer surface, perimeter, or edge of the build-up regions 132 and/or the outer surface, perimeter, or edge of the package lid 112). As a result, in some examples, one or both opposing surfaces of the glass core are exposed to the environment external to the IC package 100. In some examples, one or more of the contact pads 120 are coupled to corresponding metal transmission line(s) 138 (e.g., metal interconnect(s)) that extend into the protrusion 134. In the illustrated example, the metal transmission line 138 extends along a middle (e.g., through an interior) of the glass core 130 in a directional substantially parallel to exterior surfaces of the glass core 130 (e.g., spaced apart from and between the opposing sides or outer surfaces of the glass core 130). As used herein, substantially parallel means exactly parallel or within 10 degrees of exactly parallel. In other examples, the metal transmission line 138 can extend along one side or outer surface of the glass core 130. The protrusion 134 of the glass core 130 in combination with the metal transmission line 138 disposed therein define a pluggable interconnect 140 (e.g., an external pluggable connector, also referred to herein as a plug) that can be plugged into a receiving socket 142 of a plug connector 144 that is communicatively coupled with an external component 146 (e.g., external to and separate and/or distinct from the package 100). Thus, the protrusion 134 and/or the pluggable interconnect 140 is an example means for inserting into a socket of a plug connector. The metal transmission line 138 functions as a wire or interconnect to transmit signals and/or define a signal path for signals sent between the semiconductor die(s) 106, 108 and the external component 146 (via the plug connector 144). Thus, the metal transmission line 138 is an example means for transmitting a signal. Although only one metal transmission line 138 is shown, in some examples, the pluggable interconnect 140 includes multiple transmission lines defining multiple different signal paths. In some examples, the plug connector 144 can be selectively added or removed from the pluggable interconnect 140. In some examples, one plug connector (e.g., the plug connector 144 of FIG. 1) can be replaced by a separate plug connector (coupled to the same external component 146 and/or to a different external component).

Providing a pluggable interconnect 140 using the glass core 130 enables communication links to be established between components external to the IC package 100 independent of internal interconnects 126 extending all the way through (e.g., without using up space within) the build-up regions 132. As a result, there is more space in the build-up regions 132 for other purposes (e.g., metal traces and/or routing for other internal interconnects 126). Aside from the benefit of reducing limitations on space for conductive routing, pluggable interconnects 140 can also provide additional bandwidth to what may be achieved by standard internal interconnects 126 for a given substrate size (e.g., a given number of metal layers in the build-up regions 132). Examples disclosed herein not only reduce routing limitations within the build-up regions 132 of the package substrate 110, but can also reduce the overall size of the package by reducing the number of second level interconnects needed to connect the package 100 to the circuit board 102. This, in turn, can reduce the size and/or complexity of the circuit board 102 and/or a socket on the circuit board and can also reduce insertion loss. Another advantage of implementing pluggable interconnects 140 within a glass core 130 is that it reduces (e.g., avoids) the insertion loss, signal integrity issues (e.g., based on large structural features), and/or unwanted crosstalk that arises for high data rate (e.g., high frequency) second level interconnects otherwise achieved by plated though holes in the circuit board 102. Further still, enabling off-package communications through the pluggable interconnect 140 can reduce latency relative to electrical interconnects routed through the entire package substrate 110, the second level interconnects, and through the circuit board 102.

In some examples, the pluggable interconnect 140 and the associated socket 142 of the plug connector 144 are constructed to wirelessly communicate based on near field electromagnetic radiation (e.g., via inductive coupling, capacitive coupling (e.g., alternating current (AC) coupling), or radiative coupling). Such near field communication eliminates the need for direct physical contact of conductive elements (e.g., conductive coupling), thereby improving reliability and reducing the probability of communication errors due to relative movement caused by vibrations or the like. Furthermore, points of direct physical contact can wear away over time through repeated use. Thus, wireless (contactless) communications can reduce the effects of wear on the pluggable interconnect 140 from repeated attachment and removal of the plug connector 144. In other examples, the pluggable interconnect 140 and the associated socket 142 of the plug connector 144 are constructed with conductive contacts that enable the direct conductive coupling of the components.

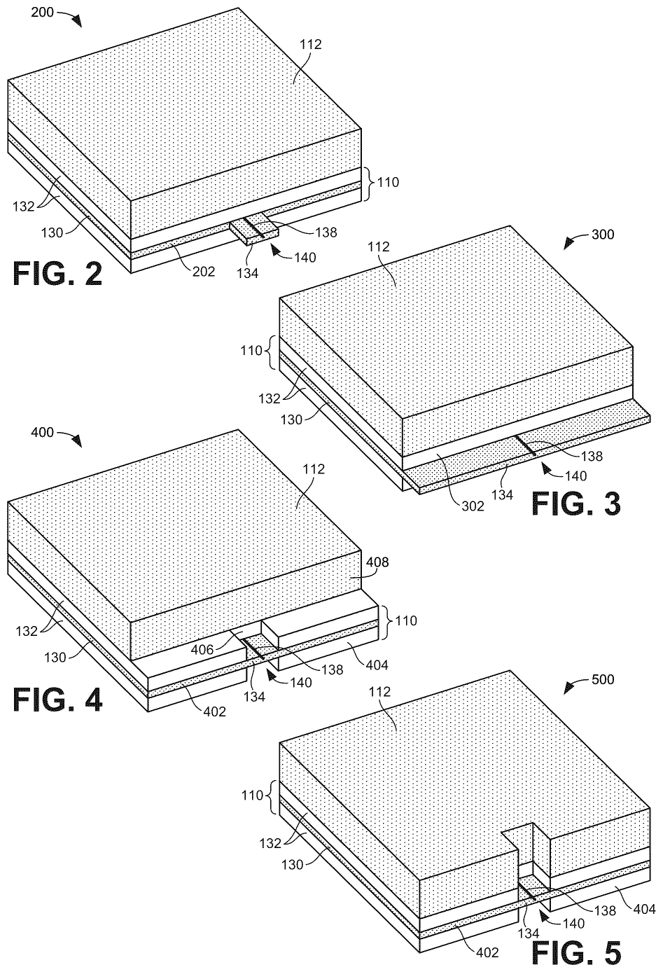

FIGS. 2-5 are perspective views of different example IC packages 200, 300, 400, 500 constructed in accordance with teachings disclosed herein. Each of the example packages 200, 300, 400, 500 in FIGS. 2-5 may correspond to the example package 100 of FIG. 1. Accordingly, the same reference numbers used in FIG. 1 are used in FIGS. 2-5 for the same or similar components. Thus, as shown in FIGS. 2-5, the example packages 200, 300, 400, 500 include a package substrate 110 defined by a glass core 130 with build-up regions 132 disposed on either side. The package substrate 110 supports one or more dies (e.g., the dies 106, 108 of FIG. 1), which are not shown in FIGS. 2-5 because the die(s) are covered by a lid 112.

Each of FIGS. 2-5 illustrate different example implementations of the pluggable interconnect 140 of FIG. 1. For instance, in FIG. 2, the portion of the glass core 130 corresponding to the protrusion 134 is a limited segment of glass core 130 corresponding to less than a full length of an edge 202 of the glass core 130 along which the protrusion 134 is located. As shown in the illustrated example, the metal transmission line 138 is positioned within the center of the protrusion 134. However, the metal transmission line 138 can be located anywhere within and/or on the protrusion 134 of the pluggable interconnect 140 and can have any suitable shape. In some examples, the pluggable interconnect 140 includes more than one metal transmission line 138. In some examples, the package 200 of FIG. 2 includes more than one protrusion 134 extending away from the edge 202 of the glass core 130 to define multiple different pluggable interconnects 140. Additionally or alternatively, in some examples, protrusions similar to the protrusion 134 shown in FIG. 2 can protrude from more than one of the edges of the glass core 130 to provide pluggable interconnects 140 on more than one side of the package 200.

In FIG. 3, the protrusion 134 corresponds to the full length of the glass core 130 along one lateral side or edge 302 of the package 300. In this example, the metal transmission line 138 is positioned within the center of the protrusion 134. However, the metal transmission line 138 can be located anywhere within and/or on the protrusion 134 and have any suitable shape. Further, in some examples, more than one metal transmission line 138 is positioned along the length of the protrusion 134 to define multiple different pluggable interconnects 140 (and/or multiple transmission lines for a single pluggable interconnect 140). That is, although there is only one continuous protrusion shown in FIG. 3 (extending the full length of the edge of the glass core 130), in some examples, different segments or portions of the protrusion 134 correspond to different pluggable interconnects (e.g., that connect or plug into separate plug connectors 144. Additionally or alternatively, in some examples, the glass core 130 can protrude along a full length of more than one lateral side or edge 302 of the package 300 to provide for pluggable interconnects 140 on more than one side of the package 300.

In FIG. 4, the protrusion 134 corresponds to a segment (as opposed to the full length) of the glass core 130 along one edge 402 of the glass core. In this example, the segment of the glass core 130 is limited to a section of the glass core 130 between opposite ends of the edge of the glass core 130. In this example, the limited section of the glass core 130 does not protrude from the edge 402 of the glass core 130 (as in FIG. 2) or an outer edge 404 of the build-up regions 132 (as in FIG. 3). Rather, in the illustrated example of FIG. 4, the outer edge of the protrusion 134 is coterminous with the outer edges 402, 404 of both the glass core 130 and the build-up regions 132. However, the protrusion 134 protrudes from a recessed surface 406 of the build-up regions 132 that is recessed relative to the outer edge 404 of the build-up regions 132. In this example, the protrusion 134 also protrudes from the outer edge 408 of the lid 112. In other words, an entire edge of the substrate 110 protrudes from the lid 112 with a portion of the build-up regions 132 removed to expose the segment of the glass core 130 corresponding to the protrusion 134. In the illustrated example of FIG. 4, the metal transmission line 138 is positioned within the center of the protrusion 134. However, the metal transmission line 138 can be located anywhere within and/or on the protrusion 134 for the pluggable interconnect 140 and can have any suitable shape. In some examples, the pluggable interconnect 140 includes more than one metal transmission line 138. Further, in some examples, multiple different portions of the build-up regions 132 may be removed to expose different segments of the glass core 130 corresponding to different pluggable interconnects 140. Additionally or alternatively, in some examples, pluggable interconnects 140 constructed as shown in FIG. 4 can be provided on more than one side of the example package 400.

The example package 500 of FIG. 5 is similar to the example package 400 of FIG. 4 except that the lid 212 extends to the outer edges 402, 404 of the glass core 130 and the build-up regions 132. Further, as shown in FIG. 5, the lid 112 includes a cavity or recess aligned with the recessed portion of the build-up regions 132 to expose a portion of the glass core 130 corresponding to the protrusion 134 to implement the pluggable interconnect 140. Although one pluggable interconnect 140 is shown in FIG. 5, any suitable number of pluggable interconnects 140 may be provided along the same edge of the package 500 and/or on more than one edge of the package 500. Further, as in the above examples, the metal transmission line 138 can have any suitable shape and/or be one of multiple metal transmission lines 138 associated with the pluggable interconnect 140. In some examples, different ones of the pluggable interconnects 140 shown in FIGS. 2-5 can be implemented within the same IC package. Thus, the features shown and described in each of FIGS. 2-5 are not mutually exclusive but may be combined in any suitable manner and/or aspects shown in one figure may be used in addition to and/or instead of any aspect shown in one of the other figures.

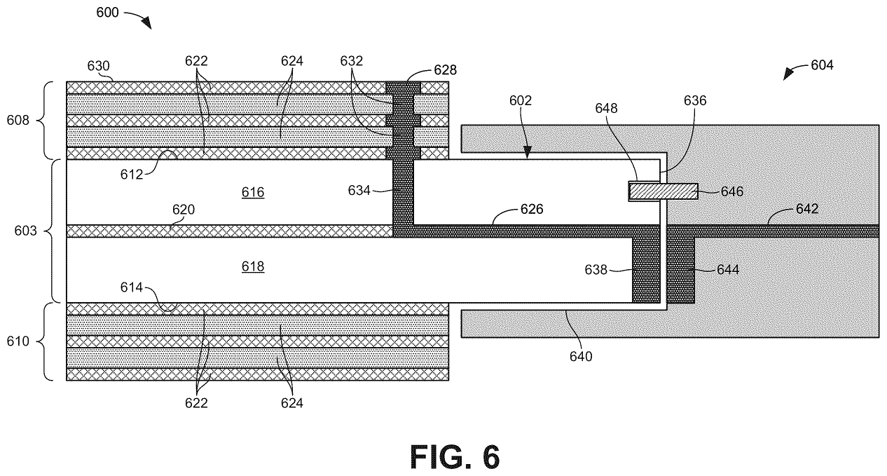

FIG. 6 is a cross-sectional view of an example package substrate 600 with a pluggable interconnect 602 plugged into a plug connector 604 in accordance with teachings disclosed herein. The package substrate 600 of FIG. 6 can serve as or correspond to the package substrate 110 in any one of the example packages 100, 200, 300, 400, 500 of FIGS. 1-5. As shown in FIG. 6, the package substrate 600 includes a glass core 606, and first and second build-up layers or regions 608, 610 on respective first and second sides or surfaces 612, 614 of the glass core 606. As shown in the illustrated example, the glass core 603 is defined by two layers of glass 616, 618 with an intermediate layer 620 disposed therebetween. In some examples, the glass core 603 includes more than two layers of glass. The adhesive layer or intermediate layer 516 can include any suitable low loss adhesive (e.g., AJINOMOTO BUILD-UP FILM™ (ABF) material) to facilitate the bonding of the two glass layers 616, 618. Further, in some examples, the intermediate layer 620 may also function as a metal layer with patterned metal disposed therein. In some examples, the intermediate layer 620 is omitted and the two glass layers 616, 618 are bonded directly together. In some examples, the glass core 603 corresponds to a single unitary layer of glass (with no intermediate layer 620).

In the illustrated example of FIG. 6, each of the build-up regions 608, 610 includes three conductive (e.g., metal) layers 622 separated by two dielectric layers 624. In other examples, there may be fewer or more metal layers 622 and/or dielectric layers 624 than shown in the illustrated example. The metal layers 622 are shown extending continuously across the length or width of the glass core 603 for purposes of explanation and simplicity. That is, as discussed above, the actual location(s) of metal within the metal layers 622 may not be continuous and depends upon the way in which the metal has been patterned within the metal layers 622 to define electrical traces, routing, contact pads, etc. Location(s) in which there is no metal in the metal layers 622 of FIG. 6 can be filled with the dielectric material associated with the dielectric layers 624 during the process of fabricating the build-up regions 608, 610 (e.g., via the successive lamination of the dielectric layers 624 onto the underlying metal layers 622 after lithographically patterning the metal in the underlying metal layer). Further, for the sake of simplicity, metal vias extending through the dielectric layers 624 have also been omitted in FIG. 6. However, metal associated with a metal transmission line 626 for the pluggable interconnect 602 is shown in FIG. 6.

As shown in this example, the metal transmission line 626 begins at a contact pad 628 on the upper surface 630 of the substrate 600 (e.g., corresponding to one of the contact pads 120 on the inner surface 122 of the substrate 110 of FIG. 1). The metal transmission line 626 extends through the first (upper) build-up region 608 through a series of metal vias 632 down to the glass core 603. The metal transmission line 626 then extends through the first layer of glass 616 by way of a through-glass via (TGV) 634 to the intermediate layer 620 and along the intermediate layer 620 to a distal end 636 of the glass core 603 protruding beyond the build-up regions 608, 610. As discussed above, in some examples, the two glass layers 616, 618 are bonded directly together without an intermediate layer 620 therebetween. In some such examples, an elongate trench or cavity is etched into one or both of the glass layers 616, 618 to provide space for the metal transmission line 626. In examples where the glass core 130 corresponds to a single unitary layer of glass, the metal transmission line 626 can extend along an outer surface of the glass core 130 (e.g., along the first surface 612).

In the illustrated example, the metal transmission line 626 includes a terminal segment 638 that extends along the distal end 636 of glass core 603. More particularly, in this example, the terminal segment 638 extends along the distal end of the second layer of glass 618 between opposing surfaces of the glass layer (e.g., in a direction substantially perpendicular to the main dimensions or plane of the glass core 603). In other examples, the terminal segment 638 extends along the distal end of the first layer of glass 616. In some examples, the terminal segment 638 extends along the distal ends of both layers of glass 616, 618. Unlike what is shown in the illustrated example, in some examples, the terminal segment 638 extends only part way along the thickness of the distal end of the first and/or second layers of glass 616, 618. In some examples, the terminal segment 638 is omitted and the metal transmission line 626 terminates within the intermediate layer 620.

As shown in the illustrated example, the pluggable interconnect 602 is inserted (e.g., plugged) into a socket 640 of the plug connector 604. In some examples, the plug connector 604 is composed of plastic but any other material may additionally or alternative be used. In this example, the plug connector 604 includes a metal transmission line 642 that includes a terminal segment 644 generally corresponding to the terminal segment 638 of the metal transmission line 626 in the pluggable interconnect 602. However, in other examples, the two terminal segments 638, 644 may differ in size, shape, orientation, and/or structure. In this example, the two terminal segments 638, 644 function as side radiating elements to enable contactless (wireless) coupling of the two corresponding transmission lines 626, 642. Thus, the terminal segment 638 is an example means for communicatively coupling the transmission line 626 in the pluggable interconnect 602 with the transmission line 642 in the plug connector 604. In some examples, the pluggable interconnect 602 fits within the socket 640 with relatively tight tolerances (e.g., +/−10 μm or better (e.g., +/−/5 um, +/−1.5 um)) to enable relatively precise alignment of the two terminal segments for reliable near field communications. Relatively tight tolerances are possible because the glass core 603, being made of glass, can be manufactured to mechanical tolerances significantly more precise than existing epoxy based package substrate cores. In some examples, to further facilitate the alignment of the transmission lines 626, 642, the plug connector 604 includes one or more alignment pins 646 dimensioned to fit within corresponding receiving holes 648 in the pluggable interconnect 602. Thus, the alignment pins 646 are an example means for aligning the pluggable interconnect 602 with the plug connector 604. In some examples, the pluggable interconnect 602 includes the alignment pins 646 and the plug connector 604 includes the corresponding receiving holes 648. In some such examples, the alignment pins 646 are integrally formed with the glass core 603. In other examples, the alignment pins 646 are separate components attached to the glass core 603. In some examples, the pins 646 and the associated receiving holes 648 are omitted.

In some examples, the metal transmission line 642 within the plug connector 604 is electrically coupled to any suitable external component via any suitable transmission media (e.g., cable(s), PCB trace(s), waveguide(s), etc.). The nature of the contactless coupling at high operating frequencies (e.g., at 110 GHz to 170 GHz operation) can lead to extended bandwidth to provide high data throughput without having to pass the signals down through the package substrate 600, second level interconnects, and an underlying PCB (e.g., the circuit board 102). As a result, the pluggable interconnect 602 serves to reduce motherboard (PCB) complexities, reduce package routing congestion, and improve signal integrity by reducing package and motherboard signal parasitics. Furthermore, off-package communications through the lateral side of a package using the pluggable interconnect 602 can also reduce (e.g., avoid) the need for interconnects on the topside of an associated package (e.g., the side opposite the printed circuit board). Reducing and/or avoiding topside interconnects is beneficial because it reduces challenges and/or limitations in implementing thermal solutions to cool the associated package (e.g., with a heatsink placed on the topside of the package). Of course, packages constructed in accordance with teachings disclosed herein may still be communicatively coupled via routing in the circuit board and/or through topside interconnects in addition to the pluggable interconnect 602.

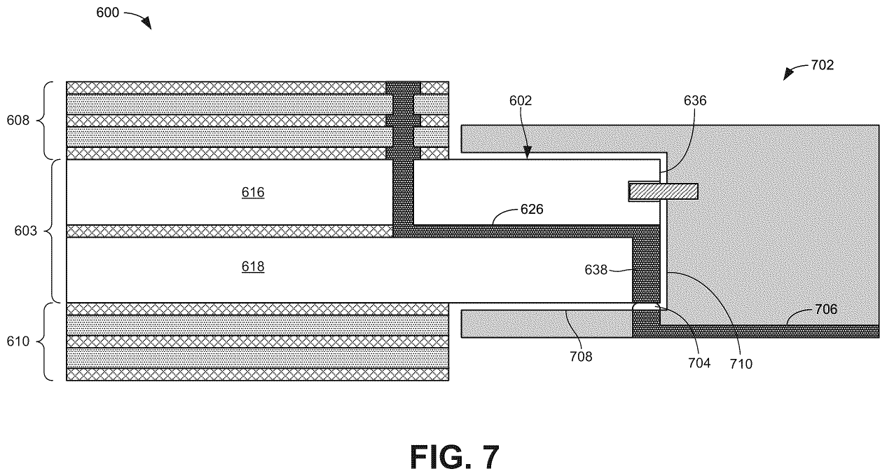

In some examples, instead of contactless coupling of the pluggable interconnect 602 and the plug connector 604, conductive coupling is employed. For instance, FIG. 7 shows the same package substrate 600 of FIG. 6 with the same pluggable interconnect 602 plugged into another example plug connector 702. The example plug connector 702 of FIG. 7 includes a conductive contact 704 that is electrically coupled to a metal transmission line 706 within the plug connector 702. As shown in the illustrated example, the conductive contact 704 protrudes from an inner surface or wall of the socket 708 to come into contact with the metal transmission line 626 (e.g., at an end of the terminal segment 638). In some examples, the conductive contact 704 includes a resilient and/or malleable component to urge the conductive contact 704 against the metal transmission line 626 of the pluggable interconnect 602 to reduce resistance between the pluggable interconnect 602 and the plug connector 702. For example, the conductive contact 704 can be implemented using crushable balls, flat springs, spring loaded pins, clips, and/or any other suitable mechanism. Although the conductive contact 704 is shown on a sidewall of the socket 708, in some examples, the conductive contact 704 can be positioned on the back wall 710 to contact a different portion of the metal transmission line 626 of the pluggable interconnect 602. In some examples, the plug connector 702 includes more than one conductive contact 704. In some examples, the pluggable interconnect 602 may include a conductive contact in addition to or instead of the conductive contact 704 on the plug connector 702. The conductive contact 704 is another example means for communicatively coupling the metal transmission line 626 in the pluggable interconnect 602 with the metal transmission line 706 in the plug connector 604.

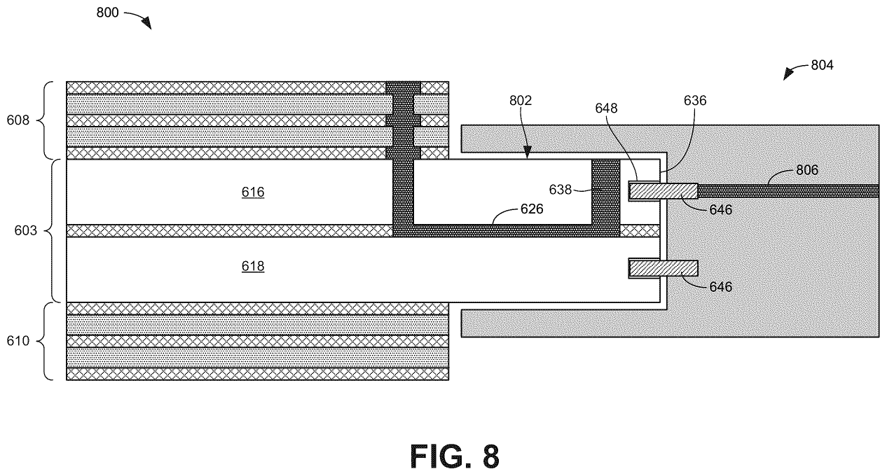

FIG. 8 is a cross-sectional view of another example package substrate 800 with a pluggable interconnect 802 plugged into a plug connector 804 in accordance with teachings disclosed herein. The package substrate 800 of FIG. 8 can serve as or correspond to the package substrate 110 in any one of the example packages 100, 200, 300, 400, 500 of FIGS. 1-5. The package substrate 800 and plug connector 804 of FIG. 8 are similar in construction to the package substrate 600 and plug connectors 604, 702 shown in FIGS. 6 and 7. Therefore, the reference numbers in FIGS. 6 and/or 7 are reproduced for corresponding components in FIG. 8 and the discussion of such components provided above in connection with FIGS. 6 and/or 7 applies equally to FIG. 8. FIG. 8 differs from FIGS. 6 and 7 in that two alignment pins 646 are shown instead of one. Further, the metal transmission line 626 in FIG. 8 does not extend all the way to the distal end 636 of the glass core 603. Instead, the terminal segment 638 extends, in this example, through the first layer of glass 616 (as a TGV) at a location that is lateral inset relative to the end of the alignment pin 646 extending into receiving hole 648 in the first layer of glass 616. In some examples, the distance between the terminal segment 638 and the alignment pin 646 enables contactless coupling (e.g., capacitive coupling) between the two components. To enable the contactless coupling, in this example, the alignment pin 646 is composed of a conductive material (e.g., metal) and is electrically (e.g., conductively) coupled to a metal transmission line 806 within the plug connector 804. Thus, in some examples, alignment pins 646 define part of the signal path for signals transmitted via the pluggable interconnect 802.

In some examples, the terminal segment 638 of the metal transmission line 626 in the pluggable connector 802 is positioned to define the base of the receiving hole 648. That is, in some examples, the receiving hole 648 extends to the terminal segment 638 to expose a portion of the terminal segment 638 to enable direct conductive coupling between the terminal segment 638 and the conductive alignment pin 646. In some examples, a resilient and/or malleable conductive contact, similar to the conductive contact 704 described above in connection with FIG. 7, is positioned between the terminal segment 638 and the end of the alignment pin 646 to reduce electrical contact resistance.

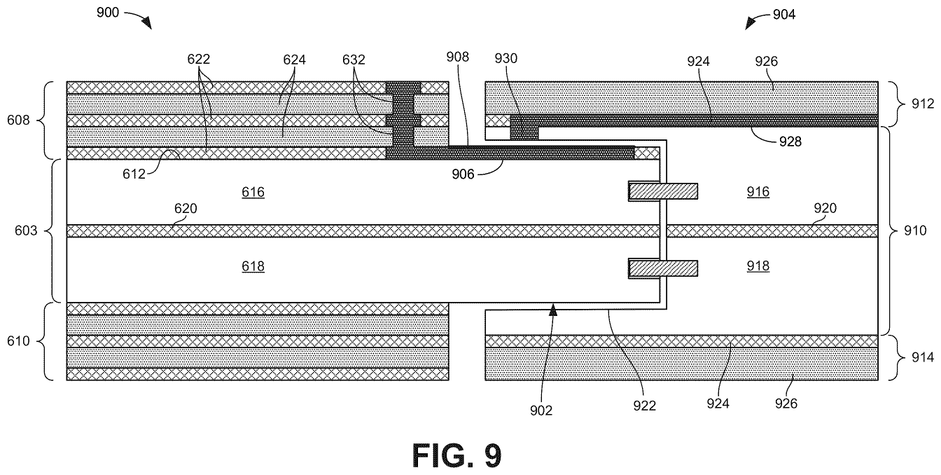

FIG. 9 is a cross-sectional view of another example package substrate 900 with a pluggable interconnect 902 plugged into a plug connector 904 in accordance with teachings disclosed herein. The package substrate 900 of FIG. 9 can serve as or correspond to the package substrate 110 in any one of the example packages 100, 200, 300, 400, 500 of FIGS. 1-5. The package substrate 900 of FIG. 9 is similar in construction to the package substrates 600, 800 shown in FIGS. 6-8. Therefore, the reference numbers in FIGS. 6-8 are reproduced for corresponding components in FIG. 9 and the discussion of such components provided above in connection with FIGS. 6-8 applies equally to FIG. 9. Unlike the package substrates 600, 800 in FIGS. 6-8, the package substrate 900 of FIG. 9 includes a metal transmission line 906 that extends along an exterior or outer surface of the pluggable interconnect 902 (e.g., the first surface 612 of the glass core 603), rather than along the intermediate layer 620 (as shown in FIGS. 6-8). As shown in the illustrated example, the portion of the metal transmission line 906 that extends along the pluggable interconnect 902 corresponds to and/or is an extension of the first metal layer 622 in the first build-up region 608. In some examples, more than one metal layer 622 (with associated dielectric layer(s) 624 disposed therebetween) extends along the length of the pluggable interconnect 902. That is, in some examples, at least a portion of the build-up regions 608, 610 can extend along outer surfaces of the portion of the glass core 603 corresponding to the pluggable interconnect 902.

Inasmuch as the transmission line 906 does not extend into the glass core 603, in some examples, the intermediate layer 620 may be omitted and/or the glass core 603 may be implemented by a single unitary layer of glass. In other examples, the exposed portion of the metal transmission line 906 on the pluggable interconnect 902 is spaced apart from the metal layers 622 in the first build-up region 608. In some such examples, the exposed portion of the transmission line 906 is electrically coupled to the rest of the metal transmission line 906 within the build-up region 608 (e.g., is electrically coupled to the metal vias 632) based on a conductive path defined through the glass core 603 (e.g., a first TGV extending down from the metal vias 632 to the intermediate layer 620, a metal trace along the intermediate layer 620, and a second TGV up to the exposed portion of metal transmission line 906).

With the metal transmission line 906 on an exposed exterior of the pluggable interconnect 902, there is an increased risk of corrosion, rusting, and/or other concerns with exposure to environmental elements. Accordingly, in some examples, the exposed metal is plated with a protective film 908. In some examples, the protective film includes gold, platinum, palladium, rhodium, and/or any other non-reactive material. The protective film 908 can also serve to increase the hardness of the exposed portion of the metal transmission line 906 to resist against wear from repeated plug insertions. In some examples, the protective film 908 is omitted.

In the illustrated example of FIG. 9, the plug connector 904 is implemented using glass core technology similar to the example package substrate 900. That is, as shown in the illustrated example, the plug connector 904 includes a glass core 910 with first and second build-up layers or regions 912, 914. In this example, the glass core 910 includes two layers of glass 916, 918 separated by an intermediate layer 920. In some examples, the intermediate layer 920 may be omitted. In some examples, the glass core 910 may be implemented by a single unitary layer of glass. In other examples, more than two layers of glass may be used. In this examples, the glass core 910 of the plug connector 904 is thicker than the glass core 603 of the package substrate 900 to define a socket 922 into which the pluggable interconnect 902 may be inserted. Inasmuch as glass can be fabricated to relatively precise mechanical tolerances, the socket 922 of the plug connector 904 (made of glass) can be defined to provide a close fit with the pluggable interconnect 902 (also made of glass).

In some examples, the build-up regions 912, 914 on either side of the glass core 910 of the plug connector can include one or more metal layers 924 and one or more dielectric layers 926 similar to the metal layers 622 and dielectric layers 624 of the package substrate 900 as detailed above in connection with FIG. 6. In this example, the metal layer 924 in the first build-up region 912 of the plug connector 904 includes a metal transmission line 928 that extends along a surface of the glass core 910. The metal transmission line 928 includes a terminal segment 930 that extends through the glass core 910 (e.g., as a TGV) to a sidewall of the socket 922 to place the metal transmission line 928 in proximity to the metal transmission line 906 extending along the pluggable interconnect 902. In this manner, the two transmission lines may be wirelessly coupled (e.g., through inductive coupling, capacitive coupling, radiative coupling). In some examples, a conductive contact (as discussed in greater detail above) is provided between the two metal transmission lines 906, 928 to enable conductive coupling of the two lines.

Although one example arrangement of the transmission lines 906, 928 are shown in FIG. 9, many other arrangements are possible. For instance, in some examples, one or both of the transmission lines 906, 928 may extend along the corresponding intermediate layers 620, 920 of the glass cores 603, 910 of the respective package substrate 900 and plug connector 904. Thus, any of the arrangements of transmission lines shown in FIGS. 6-8 may be implemented by the system shown in FIG. 9. Further, any other suitable arrangement of the transmission lines 626, 906 within the pluggable interconnects 602, 802, 902 and of the transmission lines 642, 706, 806, 928 within the plug connectors 604, 702, 804, 904 may be employed in accordance with teachings disclosed herein. Further, in some examples, any of the example pluggable interconnects 602, 802, 902 disclosed herein include multiple different transmission lines that communicatively couple (wirelessly or via direct contact) with corresponding transmission lines in the plug connectors 604, 702, 804, 904. In some examples, the different transmission lines in the pluggable interconnects 602, 802, 902 are separated by the different glass layers 616, 618 in the glass core 603. For example, a first transmission line is located on the first surface 612 of the glass core 603 (as shown in FIG. 9) and a second transmission line is located within the intermediate layer 620 (as shown in FIGS. 6-8). Additionally or alternatively, in some examples, multiple separate transmission lines can reside in the same metal layer (on an outer surface of the glass core or within the intermediate layer). In such examples, the different transmission lines are separated by being defined by spaced apart traces within the corresponding metal layer.

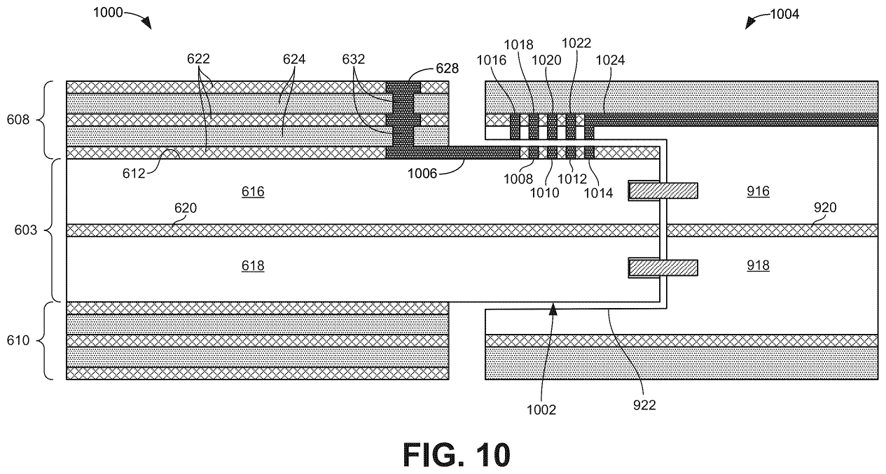

An example pluggable interconnect with multiple transmission lines is shown in FIG. 10. FIG. 10 is a cross-sectional view of another example package substrate 1000 with a pluggable interconnect 1002 plugged into a plug connector 1004 in accordance with teachings disclosed herein. The package substrate 1000 of FIG. 10 can serve as or correspond to the package substrate 110 in any one of the example packages 100, 200, 300, 400, 500 of FIGS. 1-5. The package substrate 1000 and plug connector 1004 of FIG. 10 are similar in construction to the package substrate 900 and plug connector 904 shown in FIG. 9. Therefore, the reference numbers in FIG. 9 are reproduced for corresponding components in FIG. 10 and the discussion of such components provided above applies equally to FIG. 10.

In the illustrated example of FIG. 10, the pluggable interconnect 1002 includes five separate transmission lines 1006, 1008, 1010, 1012, 1014. While five transmission lines are shown, any suitable number of transmission lines may be implemented. In this example, the full length of the first transmission line 1006 (from the contact pad 628, down through the metal vias 632, and across the first surface 612 of the glass core 603) is shown in FIG. 10. However, only the terminal ends of the other four transmission lines 1008, 1010, 1012, 1014 are shown in FIG. 10 because these transmission lines are provided either in front of or behind (from the perspective shown in FIG. 10) to the first transmission line 1006. As represented in FIG. 10, the terminal ends of all five transmission lines 1006, 1008, 1010, 1012, 1014 are in the same plane (e.g., the plane of the cross-section of FIG. 10). However, FIG. 10 is drawn in this manner for purposes of explanation. In some examples, at least some of the transmission lines 1006, 1008, 1010, 1012, 1014 terminate and/or are otherwise situated in different cross-sectional planes. Further, in some examples, as discussed above, one or more of the transmission lines 1006, 1008, 1010, 1012, 1014 is constructed to extend through some or all of the glass core 603 and/or along the intermediate layer 620. More generally, the arrangement of the transmission lines 1006, 1008, 1010, 1012, 1014 can be modified in any suitable manner.

As shown in FIG. 10, the plug connector 1004 includes five separate transmission lines 1016, 1018, 1020, 1022, 1024 corresponding to the five transmission lines 1006, 1008, 1010, 1012, 1014 in the pluggable interconnect 1002. In this example, terminal ends of ones of the transmission lines 1016, 1018, 1020, 1022, 1024 in the plug connector 1004 are aligned with the terminal ends of respective ones of the transmission lines 1006, 1008, 1010, 1012, 1014 in the pluggable interconnect 1002 to communicatively couple the respective transmission lines. In some examples, the transmission lines are coupled in a contactless (wireless) manner. In some examples, the transmission lines are coupled by a direct conductive contact (e.g., in some examples conductive contacts are positioned between respective pairs of the transmission lines 1006, 1008, 1010, 1012, 1014, 1016, 1018, 1020, 1022, 1024).

The foregoing examples of the package substrates 600, 800, 900, 1000 and the associated plug connectors 604, 702, 804, 904, 1004 of FIGS. 6-10 teach or suggest different features. Although each example package substrate 600, 800, 900, 1000 and associated plug connector 604, 702, 804, 904, 1004 disclosed above has certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features. Furthermore, any of the example package substrates 600, 800, 900, 1000 can be implemented in connection with any one of the example packages 100, 200, 300, 400, 500 of FIGS. 1-5.

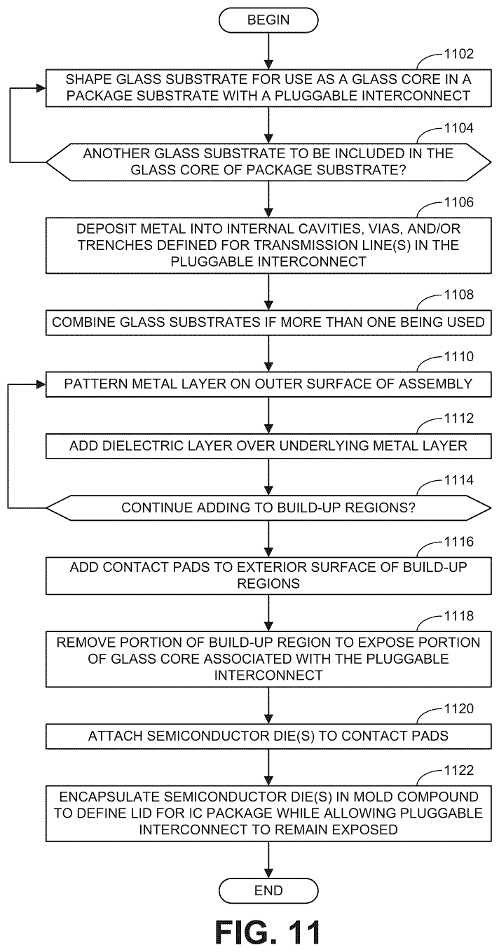

FIG. 11 is a flowchart representative of an example method of manufacturing any one of the example IC packages 100, 200, 300, 400, 500 of FIG. 1-5 with any one of the example package substrates 600, 800, 900, 1000 of FIGS. 6-10. In some examples, some or all of the operations outlined in the example method of FIG. 11 are performed automatically by fabrication equipment that is programmed to perform the operations. Although the example method of manufacture is described with reference to the flowchart illustrated in FIG. 11, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 11 begins at block 1102 by shaping a glass layer (e.g., the glass layers 616, 618) for use as a glass core (e.g., the glass core 603) in a package substrate (e.g., the package substrates 600, 800, 900, 1000) with a pluggable interconnect (e.g., the pluggable interconnects 140, 602, 802, 902, 1002). In some examples, the shaping of the glass layer 616, 618 includes etching, cutting, and/or drilling vias (TGVs), trenches, and/or cavities that define regions to be subsequently plated with metal to define metal transmission line(s) (e.g., the transmission lines 138, 626, 906, 1006, 1008, 1010, 1012, 1014) for the pluggable interconnect. In some examples, the vias, trenches, and/or cavities may also be used for other purposes (e.g., TGVs for standard internal interconnects 126). In some examples, the shaping of the glass layer 616, 618 also includes defining a protrusion that protrudes out from an edge of the glass layer (as shown in FIG. 2) to serve as the pluggable interconnect 140, 602, 802, 902, 1002. At block 1104, the method involves determining whether another glass layer 616, 618 is to be included in the glass core 603 of the package substrate 600, 800, 900, 1000. If so, operation returns to block 1102. Otherwise, the method advances to block 1106. If the glass core 603 is to be implemented by a single unitary piece of glass, block 1104 may be omitted.

At block 1106, the method involves depositing metal into internal cavities, vias, and/or trenches defined for the transmission line(s) (e.g., the transmission lines 138, 626, 906, 1006, 1008, 1010, 1012, 1014) in the pluggable interconnect 140, 602, 802, 902, 1002. In some examples, metal can be deposited for other purposes (e.g., TGVs for the standard internal interconnects 126) during this stage of the process. If there is more than one glass layer 616, 618 being used, the method involves combining the glass layers 616, 618 (block 1108). In some examples, the glass layers 616, 618 are combined with any suitable adhesive. In some examples, metal is deposited between the glass layers 616, 618 before they are combined. In some examples, separate glass layers 616, 618 are bonded directly together without an adhesive or other intermediate layer. In examples where a single glass layers defines the glass core 603, block 1108 is skipped or omitted altogether.

At block 1110, the method involves patterning a metal layer (e.g., the metal layer 622) on an outer surface of the assembly. Thereafter, at block 1112, the method involves adding a dielectric layer (e.g., the dielectric layer 624) over the underlying metal layer 622. Blocks 1110 and 1112 represent the operations associated with developing the build-up regions (e.g., the build-up regions 608, 610) on either side of the glass core 603. As discussed above, there can be any suitable number of metal layers 622 and intervening dielectric layers 624 in the build-up regions 608, 610. Accordingly, at block 1114, the method determines whether to continue adding to the build-up regions 608, 610. If so, operation returns to block 1110 to add another metal layer 622 and then another dielectric layer 624 (at block 1112). If the build-up regions 608, 610 are complete, the method advances to block 1116 where contact pads (e.g., the contact pads 104, 120, 628) are added to exterior surfaces of the build-up regions 608, 610.

At block 1116, the method involves removing a portion of the build-up regions 608, 610 to expose a portion of the glass core 603 associated with the pluggable interconnect 140, 602, 802, 902, 1002. In some examples, at least a portion of the build-up regions 608, 610 (e.g., the first metal layer 622) is left on the exposed portion of the glass core 603. In some examples, only the build-up region 608, 610 on one side of the glass core 603 is removed while the other side is left in place. In some examples, rather than removing the build-up regions 608, 610, the development of the build-up regions (at blocks 1110-1114) is performed so as not to cover the exposed portion of the glass core 603. In such examples, block 1118 may be omitted.

At block 1120, the method involves attaching semiconductor die(s) (e.g., the dies 106, 108) to the contact pads (e.g., the contact pads 120, 628). At block 1122, the method involves encapsulating the semiconductor die(s) 106, 108 in a mold compound to define a lid (e.g., the lid 112) for the IC package (e.g., the IC packages 100, 200, 300, 400, 500) while allowing the pluggable interconnect 140, 602, 802, 902, 1002 to remain exposed. In some examples, block 1118 is performed after block 1122. In some such examples, a portion of the lid 112 is also removed to expose the pluggable interconnect 140, 602, 802, 902, 1002. Thereafter, the example method of manufacture of FIG. 11 ends.

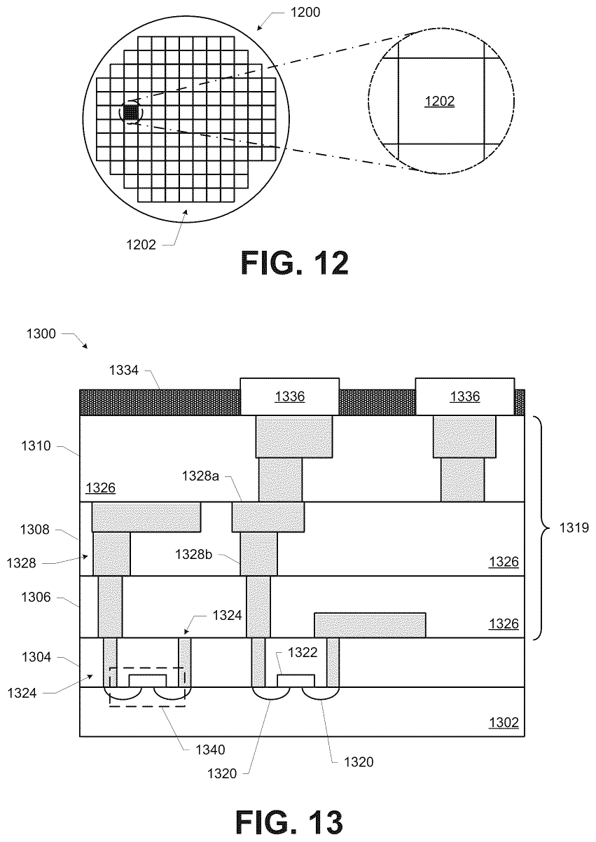

The example IC packages 100, 200, 300, 400, 500 with pluggable interconnects 140, 602, 802, 902, 1002 disclosed herein may be included in any suitable electronic component. FIGS. 12-15 illustrate various examples of apparatus that may include or be fabricated with the wireless interconnects disclosed herein.

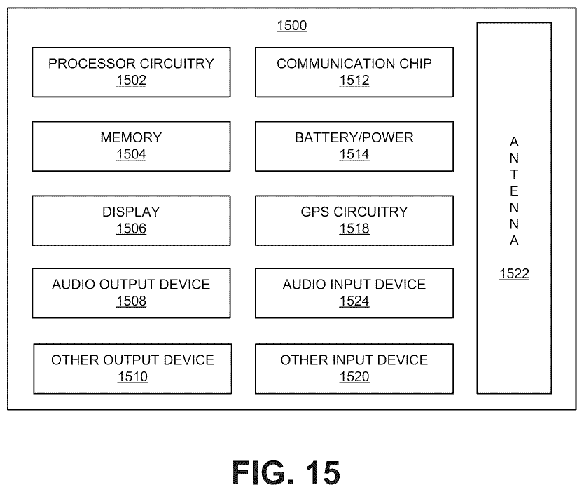

FIG. 12 is a top view of a wafer 1200 and dies 1202 that may be included in any one of the example IC packages 100, 200, 300, 400, 500 of FIGS. 1-5 (e.g., as any suitable ones of the dies 106, 108). The wafer 1200 may be composed of semiconductor material and may include one or more dies 1202 having circuitry. Each of the dies 1202 may be a repeating unit of a semiconductor product. After the fabrication of the semiconductor product is complete, the wafer 1200 may undergo a singulation process in which the dies 1202 are separated from one another to provide discrete “chips.” The die 1202 may include one or more transistors (e.g., some of the transistors 1340 of FIG. 13, discussed below), supporting circuitry to route electrical signals to the transistors, passive components (e.g., traces, resistors, capacitors, inductors, and/or other circuitry), and/or any other components. In some examples, the die 1202 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 1202. For example, a memory array formed by multiple memory circuits may be formed on a same die 1202 as programmable circuitry (e.g., the processor circuitry 1502 of FIG. 15) or other logic circuitry. Such memory may store information for use by the programmable circuitry. The example IC packages 100, 200, 300, 400, 500 disclosed herein may be manufactured using a die-to-wafer assembly technique in which some dies are attached to a wafer 1200 that include others of the dies, and the wafer 1200 is subsequently singulated.

FIG. 13 is a cross-sectional side view of an IC device 1300 that may be included in any one of the example IC packages 100, 200, 300, 400, 500 of FIGS. 1-5 (e.g., in any one of the dies 106, 108). One or more of the IC devices 1300 may be included in one or more dies 1202 (FIG. 12). The IC device 1300 may be formed on a die substrate 1302 (e.g., the wafer 1200 of FIG. 12) and may be included in a die (e.g., the die 1202 of FIG. 12). The die substrate 1302 may be a semiconductor substrate composed of semiconductor material systems including, for example, n-type or p-type materials systems (or a combination of both). The die substrate 1302 may include, for example, a crystalline substrate formed using a bulk silicon or a silicon-on-insulator (SOI) substructure. In some examples, the die substrate 1302 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1302. Although a few examples of materials from which the die substrate 1302 may be formed are described here, any material that may serve as a foundation for an IC device 1300 may be used. The die substrate 1302 may be part of a singulated die (e.g., the dies 1202 of FIG. 12) or a wafer (e.g., the wafer 1200 of FIG. 12).

The IC device 1300 may include one or more device layers 1304 disposed on or above the die substrate 1302. The device layer 1304 may include features of one or more transistors 1340 (e.g., metal oxide semiconductor field-effect transistors (MOSFETs)) formed on the die substrate 1302. The device layer 1304 may include, for example, one or more source and/or drain (S/D) regions 1320, a gate 1322 to control current flow between the S/D regions 1320, and one or more S/D contacts 1324 to route electrical signals to/from the S/D regions 1320. The transistors 1340 may include additional features not depicted for the sake of clarity, such as device isolation regions, gate contacts, and the like. The transistors 1340 are not limited to the type and configuration depicted in FIG. 13 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1340 may include a gate 1322 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1340 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1340 along the source-channel-drain direction, the gate electrode may consist of a U-shaped structure that includes a bottom portion substantially parallel to the surface of the die substrate 1302 and two sidewall portions that are substantially perpendicular to the top surface of the die substrate 1302. In other examples, at least one of the metal layers that form the gate electrode may simply be a planar layer that is substantially parallel to the top surface of the die substrate 1302 and does not include sidewall portions substantially perpendicular to the top surface of the die substrate 1302. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 1320 may be formed within the die substrate 1302 adjacent to the gate 1322 of each transistor 1340. The S/D regions 1320 may be formed using an implantation/diffusion process or an etching/deposition process, for example. In the former process, dopants such as boron, aluminum, antimony, phosphorous, or arsenic may be ion-implanted into the die substrate 1302 to form the S/D regions 1320. An annealing process that activates the dopants and causes them to diffuse farther into the die substrate 1302 may follow the ion-implantation process. In the latter process, the die substrate 1302 may first be etched to form recesses at the locations of the S/D regions 1320. An epitaxial deposition process may then be carried out to fill the recesses with material that is used to fabricate the S/D regions 1320. In some implementations, the S/D regions 1320 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1320 may be formed using one or more alternate semiconductor materials such as germanium or a group III-V material or alloy. In further examples, one or more layers of metal and/or metal alloys may be used to form the S/D regions 1320.

Electrical signals, such as power and/or input/output (I/O) signals, may be routed to and/or from the devices (e.g., transistors 1340) of the device layer 1304 through one or more interconnect layers disposed on the device layer 1304 (illustrated in FIG. 13 as interconnect layers 1306-910). For example, electrically conductive features of the device layer 1304 (e.g., the gate 1322 and the S/D contacts 1324) may be electrically coupled with the interconnect structures 1328 of the interconnect layers 1306-910. The one or more interconnect layers 1306-910 may form a metallization stack (also referred to as an “ILD stack”) 1319 of the IC device 1300.

The interconnect structures 1328 may be arranged within the interconnect layers 1306-910 to route electrical signals according to a wide variety of designs (in particular, the arrangement is not limited to the particular configuration of interconnect structures 1328 depicted in FIG. 13). Although a particular number of interconnect layers 1306-910 is depicted in FIG. 13, examples of the present disclosure include IC devices having more or fewer interconnect layers than depicted.

In some examples, the interconnect structures 1328 may include lines 1328a and/or vias 1328b filled with an electrically conductive material such as a metal. The lines 1328a may be arranged to route electrical signals in a direction of a plane that is substantially parallel with a surface of the die substrate 1302 upon which the device layer 1304 is formed. For example, the lines 1328a may route electrical signals in a direction in and out of the page from the perspective of FIG. 13. The vias 1328b may be arranged to route electrical signals in a direction of a plane that is substantially perpendicular to the surface of the die substrate 1302 upon which the device layer 1304 is formed. In some examples, the vias 1328b may electrically couple lines 1328a of different interconnect layers 1306-910 together.

The interconnect layers 1306-910 may include a dielectric material 1326 disposed between the interconnect structures 1328, as shown in FIG. 13. In some examples, the dielectric material 1326 disposed between the interconnect structures 1328 in different ones of the interconnect layers 1306-910 may have different compositions; in other examples, the composition of the dielectric material 1326 between different interconnect layers 1306-910 may be the same.

A first interconnect layer 1306 (referred to as Metal 1 or “M1”) may be formed directly on the device layer 1304. In some examples, the first interconnect layer 1306 may include lines 1328a and/or vias 1328b, as shown. The lines 1328a of the first interconnect layer 1306 may be coupled with contacts (e.g., the S/D contacts 1324) of the device layer 1304.

A second interconnect layer 1308 (referred to as Metal 2 or “M2”) may be formed directly on the first interconnect layer 1306. In some examples, the second interconnect layer 1308 may include vias 1328b to couple the lines 1328a of the second interconnect layer 1308 with the lines 1328a of the first interconnect layer 1306. Although the lines 1328a and the vias 1328b are structurally delineated with a line within each interconnect layer (e.g., within the second interconnect layer 1308) for the sake of clarity, the lines 1328a and the vias 1328b may be structurally and/or materially contiguous (e.g., simultaneously filled during a dual-damascene process) in some examples.

A third interconnect layer 1310 (referred to as Metal 3 or “M3”) (and additional interconnect layers, as desired) may be formed in succession on the second interconnect layer 1308 according to similar techniques and configurations described in connection with the second interconnect layer 1308 or the first interconnect layer 1306. In some examples, the interconnect layers that are “higher up” in the metallization stack 1319 in the IC device 1300 (i.e., further away from the device layer 1304) may be thicker.

The IC device 1300 may include a solder resist material 1334 (e.g., polyimide or similar material) and one or more conductive contacts 1336 formed on the interconnect layers 1306-910. In FIG. 13, the conductive contacts 1336 are illustrated as taking the form of bond pads. The conductive contacts 1336 may be electrically coupled with the interconnect structures 1328 and configured to route the electrical signals of the transistor(s) 1340 to other external devices. For example, solder bonds may be formed on the one or more conductive contacts 1336 to mechanically and/or electrically couple a chip including the IC device 1300 with another component (e.g., a circuit board). The IC device 1300 may include additional or alternate structures to route the electrical signals from the interconnect layers 1306-910; for example, the conductive contacts 1336 may include other analogous features (e.g., posts) that route the electrical signals to external components.

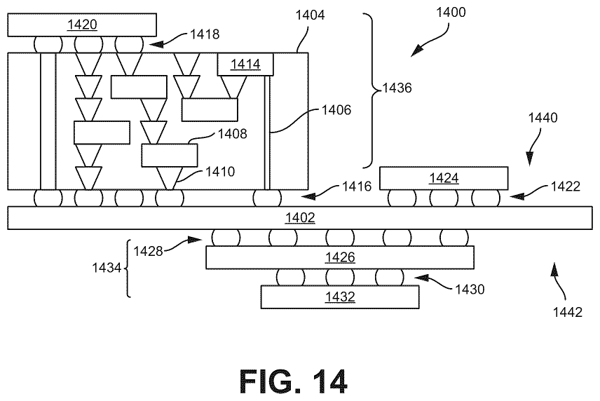

FIG. 14 is a cross-sectional side view of an IC device assembly 1400 that may include the any one of the example IC packages 100, 200, 300, 400, 500 of FIGS. 1-5 with one or more pluggable interconnect 140, 602, 802, 902, 1002 as disclosed herein. In some examples, the IC device assembly corresponds to one of the IC packages 100, 200, 300, 400, 500 of FIGS. 1-5. The IC device assembly 1400 includes a number of components disposed on a circuit board 1402 (which may be, for example, a motherboard). The IC device assembly 1400 includes components disposed on a first face 1440 of the circuit board 1402 and an opposing second face 1442 of the circuit board 1402; generally, components may be disposed on one or both faces 1440 and 1442. Any of the IC packages discussed below with reference to the IC device assembly 1400 may take the form of any one of the example IC packages 100, 200, 300, 400, 500 of FIGS. 1-5 with one or more pluggable interconnects 140, 602, 802, 902, 1002.

In some examples, the circuit board 1402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1402. In other examples, the circuit board 1402 may be a non-PCB substrate.

The IC device assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), male and female portions of a socket, an adhesive, an underfill material, and/or any other suitable electrical and/or mechanical coupling structure.

The package-on-interposer structure 1436 may include an IC package 1420 coupled to an interposer 1404 by coupling components 1418. The coupling components 1418 may take any suitable form for the application, such as the forms discussed above with reference to the coupling components 1416. Although a single IC package 1420 is shown in FIG. 14, multiple IC packages may be coupled to the interposer 1404; indeed, additional interposers may be coupled to the interposer 1404. The interposer 1404 may provide an intervening substrate used to bridge the circuit board 1402 and the IC package 1420. The IC package 1420 may be or include, for example, a die (the die 1202 of FIG. 12), an IC device (e.g., the IC device 1300 of FIG. 13), or any other suitable component. Generally, the interposer 1404 may spread a connection to a wider pitch or reroute a connection to a different connection. For example, the interposer 1404 may couple the IC package 1420 (e.g., a die) to a set of BGA conductive contacts of the coupling components 1416 for coupling to the circuit board 1402. In the example illustrated in FIG. 14, the IC package 1420 and the circuit board 1402 are attached to opposing sides of the interposer 1404; in other examples, the IC package 1420 and the circuit board 1402 may be attached to a same side of the interposer 1404. In some examples, three or more components may be interconnected by way of the interposer 1404.

In some examples, the interposer 1404 may be formed as a PCB, including multiple metal layers separated from one another by layers of dielectric material and interconnected by electrically conductive vias. In some examples, the interposer 1404 may be formed of an epoxy resin, a fiberglass-reinforced epoxy resin, an epoxy resin with inorganic fillers, a ceramic material, or a polymer material such as polyimide. In some examples, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through-silicon vias (TSVs) 1406. The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art.

The IC device assembly 1400 may include an IC package 1424 coupled to the first face 1440 of the circuit board 1402 by coupling components 1422. The coupling components 1422 may take the form of any of the examples discussed above with reference to the coupling components 1416, and the IC package 1424 may take the form of any of the examples discussed above with reference to the IC package 1420.

The IC device assembly 1400 illustrated in FIG. 14 includes a package-on-package structure 1434 coupled to the second face 1442 of the circuit board 1402 by coupling components 1428. The package-on-package structure 1434 may include a first IC package 1426 and a second IC package 1432 coupled together by coupling components 1430 such that the first IC package 1426 is disposed between the circuit board 1402 and the second IC package 1432. The coupling components 1428, 1430 may take the form of any of the examples of the coupling components 1416 discussed above, and the IC packages 1426, 1432 may take the form of any of the examples of the IC package 1420 discussed above. The package-on-package structure 1434 may be configured in accordance with any of the package-on-package structures known in the art.

FIG. 15 is a block diagram of an example electrical device 1500 that may include one or more of the example IC packages 100, 200, 300, 400, 500 of FIGS. 1-5 with pluggable interconnects 140, 602, 802, 902, 1002. For example, any suitable ones of the components of the electrical device 1500 may include one or more of the device assemblies 1400, IC devices 1300, or dies 1202 disclosed herein, and may be arranged in the example IC packages 100, 200, 300, 400, 500. A number of components are illustrated in FIG. 15 as included in the electrical device 1500, but any one or more of these components may be omitted or duplicated, as suitable for the application. In some examples, some or all of the components included in the electrical device 1500 may be attached to one or more motherboards. In some examples, some or all of these components are fabricated onto a single system-on-a-chip (SoC) die.

Additionally, in various examples, the electrical device 1500 may not include one or more of the components illustrated in FIG. 15, but the electrical device 1500 may include interface circuitry for coupling to the one or more components. For example, the electrical device 1500 may not include a display 1506, but may include display interface circuitry (e.g., a connector and driver circuitry) to which a display 1506 may be coupled. In another set of examples, the electrical device 1500 may not include an audio input device 1524 (e.g., microphone) or an audio output device 1508 (e.g., a speaker, a headset, earbuds, etc.), but may include audio input or output device interface circuitry (e.g., connectors and supporting circuitry) to which an audio input device 1524 or audio output device 1508 may be coupled.

The electrical device 1500 may include programmable circuitry 1502 (e.g., one or more processing devices). The programmable circuitry 1502 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1500 may include a memory 1504, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1504 may include memory that shares a die with the programmable circuitry 1502. This memory may be used as cache memory and may include embedded dynamic random access memory (eDRAM) or spin transfer torque magnetic random access memory (STT-MRAM).

In some examples, the electrical device 1500 may include a communication chip 1512 (e.g., one or more communication chips). For example, the communication chip 1512 may be configured for managing wireless communications for the transfer of data to and from the electrical device 1500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1512 may implement any of a number of wireless standards or protocols, including but not limited to Institute for Electrical and Electronic Engineers (IEEE) standards including Wi-Fi (IEEE 1202.11 family), IEEE 1202.16 standards (e.g., IEEE 1202.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 1202.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1202.16 standards. The communication chip 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1512 may operate in accordance with other wireless protocols in other examples. The electrical device 1500 may include an antenna 1522 to facilitate wireless communications and/or to receive other wireless communications (such as AM or FM radio transmissions).

In some examples, the communication chip 1512 may manage wired communications, such as electrical, optical, or any other suitable communication protocols (e.g., the Ethernet). As noted above, the communication chip 1512 may include multiple communication chips. For instance, a first communication chip 1512 may be dedicated to shorter-range wireless communications such as Wi-Fi or Bluetooth, and a second communication chip 1512 may be dedicated to longer-range wireless communications such as global positioning system (GPS), EDGE, GPRS, CDMA, WiMAX, LTE, EV-DO, or others. In some examples, a first communication chip 1512 may be dedicated to wireless communications, and a second communication chip 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display 1506 (or corresponding interface circuitry, as discussed above). The display 1506 may include any visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any device that generates an audible indicator, such as speakers, headsets, or earbuds.

The electrical device 1500 may include an audio input device 1524 (or corresponding interface circuitry, as discussed above). The audio input device 1524 may include any device that generates a signal representative of a sound, such as microphones, microphone arrays, or digital instruments (e.g., instruments having a musical instrument digital interface (MIDI) output).

The electrical device 1500 may include GPS circuitry 1518. The GPS circuitry 1518 may be in communication with a satellite-based system and may receive a location of the electrical device 1500, as known in the art.

The electrical device 1500 may include any other output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include any other input device 1520 (or corresponding interface circuitry, as discussed above). Examples of the other input device 1520 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1500 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable pluggable interconnect(s) in a glass core of a package substrate of an IC package to enable off-package communications without the signals being transmitted through a printed circuit board. As a result, examples disclosed herein reduce real estate within build-up layers of the package substrate, thereby enabling smaller packages, reducing congestion of second level interconnects, and/or increasing IO bandwidth for a given package size.

Further examples and combinations thereof include the following:

Example 1 includes an apparatus comprising a semiconductor die, a substrate including a glass core, and a pluggable interconnect including a portion of the glass core, the pluggable interconnect including a transmission line extending along the portion of the glass core.

Example 2 includes the apparatus of example 1, wherein the substrate includes a first build-up region on a first side of the glass core and a second build-up region on a second side of the glass core, the pluggable interconnect protruding beyond a lateral edge of at least one of the first build-up region or the second build-up region.

Example 3 includes the apparatus of example 1, wherein the portion of the glass core associated with the pluggable interconnect is exposed to an environment external to the apparatus.

Example 4 includes the apparatus of example 1, wherein the transmission line extends along an exterior surface the glass core.

Example 5 includes the apparatus of example 1, wherein the transmission line extends through an interior of the glass core in a direction substantially parallel to exterior surfaces of the glass core.

Example 6 includes the apparatus of example 5, wherein the glass core includes a first glass layer and a second glass layer, the transmission line between the first and second glass layers.

Example 7 includes the apparatus of example 6, wherein the glass core includes an adhesive layer between the first and second glass layers, the transmission line to extend along the glass core within the adhesive layer.

Example 8 includes the apparatus of example 6, wherein the first glass layer is directly bonded to the second glass layer without an intermediate layer of material therebetween.

Example 9 includes the apparatus of example 1, wherein the transmission line is one of a plurality of transmission lines included in the pluggable interconnect.

Example 10 includes the apparatus of example 1, further including a socket to receive the pluggable interconnect.

Example 11 includes the apparatus of example 10, wherein the transmission line is a first transmission line, and the socket includes a second transmission line, the first transmission line to communicatively couple with the second transmission line to define a path for a signal from the semiconductor die to an external component.

Example 12 includes the apparatus of example 11, wherein the first and second transmission lines are wirelessly coupled.

Example 13 includes the apparatus of example 11, wherein the first and second transmission lines are conductively coupled.

Example 14 includes the apparatus of example 11, wherein the glass core is a first glass core, and the socket is associated with a second glass core.

Example 15 includes the apparatus of example 14, wherein the socket includes a build-up region on the second glass core, the second transmission line in the build-up region.

Example 16 includes the apparatus of example 10, wherein the socket is defined in a plug connector, and the apparatus further includes an alignment pin on one of the pluggable interconnect or the plug connector, the alignment pin to be received into a hole in the other one of the pluggable interconnect or the plug connector.

Example 17 includes the apparatus of example 16, wherein the alignment pin is conductive, both the alignment pin and the transmission line defining portions of a signal path for a signal transmitted from the semiconductor die.

Example 18 includes an apparatus comprising means for supporting a semiconductor die, means for strengthening the means for supporting, the means for strengthening including means for inserting into a socket of a plug connector, and means for transmitting a signal within the means for inserting.

Example 19 includes the apparatus of example 18, further including means for communicatively coupling the means for transmitting with a transmission line in the plug connector.

Example 20 includes the apparatus of example 18, further including means for aligning the means for inserting with the plug connector.

Example 21 includes the apparatus of example 18, wherein the means for strengthening includes first means for strengthening and second means for strengthening, the means for communicatively coupling located between the first and second means for strengthening.

Example 22 includes a method comprising depositing metal on a glass core of a package substrate of an integrated circuit package, the metal to define a transmission line, and adding a build-up layer onto the glass core such that a portion of the glass core carrying the transmission line protrudes beyond a lateral edge of the build-up layer to define a plug.

Example 23 includes the method of example 22, further including removing the build-up layer from the portion of the glass core corresponding to the plug.

Example 24 includes the method of example 22, wherein the glass core includes at least two layers of glass, the at least two layers of glass including a first layer of glass and a second layer of glass, the method further including combining the first and second layers of glass to define the glass core.

Example 25 includes the method of example 24, wherein the depositing of the metal on the glass core is performed before the first and second layers of glass are combined to position the transmission line between the first and second layers of glass.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
a semiconductor die;
a substrate including a glass core; and
a pluggable interconnect including a portion of the glass core, the pluggable interconnect including a transmission line extending along the portion of the glass core.

2. The apparatus of claim 1, wherein the substrate includes a first build-up region on a first side of the glass core and a second build-up region on a second side of the glass core, the pluggable interconnect protruding beyond a lateral edge of at least one of the first build-up region or the second build-up region.

3. The apparatus of claim 1, wherein the portion of the glass core associated with the pluggable interconnect is exposed to an environment external to the apparatus.

4. The apparatus of claim 1, wherein the transmission line extends along an exterior surface the glass core.

5. The apparatus of claim 1, wherein the transmission line extends through an interior of the glass core in a direction substantially parallel to exterior surfaces of the glass core.

6. The apparatus of claim 5, wherein the glass core includes a first glass layer and a second glass layer, the transmission line between the first and second glass layers.

7. The apparatus of claim 6, wherein the glass core includes an adhesive layer between the first and second glass layers, the transmission line to extend along the glass core within the adhesive layer.

8. (canceled)

9. The apparatus of claim 1, wherein the transmission line is one of a plurality of transmission lines included in the pluggable interconnect.

10. The apparatus of claim 1, further including a socket to receive the pluggable interconnect.

11. The apparatus of claim 10, wherein the transmission line is a first transmission line, and the socket includes a second transmission line, the first transmission line to communicatively couple with the second transmission line to define a path for a signal from the semiconductor die to an external component.

12. The apparatus of claim 11, wherein the first and second transmission lines are wirelessly coupled.

13. The apparatus of claim 11, wherein the first and second transmission lines are conductively coupled.

14. The apparatus of claim 11, wherein the glass core is a first glass core, and the socket is associated with a second glass core.

15. (canceled)

16. The apparatus of claim 10, wherein the socket is defined in a plug connector, and the apparatus further includes an alignment pin on one of the pluggable interconnect or the plug connector, the alignment pin to be received into a hole in the other one of the pluggable interconnect or the plug connector.

17. The apparatus of claim 16, wherein the alignment pin is conductive, both the alignment pin and the transmission line defining portions of a signal path for a signal transmitted from the semiconductor die.

18. An apparatus comprising:
means for supporting a semiconductor die;
means for strengthening the means for supporting, the means for strengthening including means for inserting into a socket of a plug connector; and
means for transmitting a signal within the means for inserting.

19. The apparatus of claim 18, further including means for communicatively coupling the means for transmitting with a transmission line in the plug connector.

20. The apparatus of claim 18, further including means for aligning the means for inserting with the plug connector.

21. (canceled)

22. A method comprising:
depositing metal on a glass core of a package substrate of an integrated circuit package, the metal to define a transmission line; and
adding a build-up layer onto the glass core such that a portion of the glass core carrying the transmission line protrudes beyond a lateral edge of the build-up layer to define a plug.

23. The method of claim 22, further including removing the build-up layer from the portion of the glass core corresponding to the plug.

24. (canceled)

25. (canceled)
